(19) United States
(12) Patent Application Publication
(10) Pub. No.: US 2007/0075364 A1
(43) Pub. Date: Apr. 5, 2007

(54) Power MOSFETs and methods of making same

(75) Inventors: Kin On Johnny Sin, Hong Kong SAR (CN); Mau Lam Tommy Lai, Hong Kong SAR (CN); Duc Quang Chau, San Jose, CA (US)

Correspondence Address: BUCHANAN, INGERSOLL & ROONEY PC, POST OFFICE BOX 1404, ALEXANDRIA, VA, 22313-1404, US

(73) Assignee: ANALOG POWER INTELLECTUAL PROPERTIES LIMITED, Hong Kong SAR (CN)

(21) Appl. No.: 11/482,162

(22) Filed: Jul. 7, 2006

(30) Foreign Application Priority Data
Sep. 30, 2005 (CN) 05108715.2

(51) Int. Cl. H01L 29/76

(52) U.S. Cl. 257/341

(57) ABSTRACT

A MOSFET comprising an epitaxial layer of a semiconductor substrate of a first conductivity type, the MOSFET comprises a polysilicon gate, a source region of the first conductivity type and a body region of a second conductivity type, the polysilicon gate comprises a first layer of polysilicon and a second layer of polysilicon sandwiching a layer of polysilicon etch stop substances.

### FIELD OF THE INVENTION

This invention relates to MOSFETs and, more particularly, to power MOSFETs. More specifically, although of course not solely limited there to, this invention relates to planar VDMOS (Vertical Double-diffused MOSFET) with a high cell density, a shallow body-junction and a short channel length and methods of making same.

### BACKGROUND OF THE INVENTION

MOSFETs (Metal-Oxide-Semiconductor Field Effect Transistors), especially power MOSFETS, are widely used in electronic devices, appliances and apparatus. Exemplary applications of power MOSFETs can be found in, for example, power management and DC/DC conversion for desktop and notebook computers, mobile devices and automotive electronics. In many applications, a power MOSFET is used as a switching device whereby power delivery from a power source to a load can be varied by high frequency switching. For such applications, it is highly desirable that the on-resistance is as low as possible so that power loss across the device is minimal and the switching speed is as high as possible so that a wide range of power adjustment can be made. In addition, the cell pitch (that is, the separation between adjacent transistor cells) must be as small as possible since a plurality of transistor cells are connected in parallel to cope with a large current flow.

Planar VDMOS (Vertical Double-diffused MOS) transistor is one of the most widely used power MOSFET. In a conventional planar VDMOS, the poly-silicon at the gate region (“gate polysilicon”) is formed by masking and subsequent etching of a single polysilicon layer. The body region is formed by implantation of impurities into the epitaxial layer and by subsequent driving of the impurities laterally underneath the gate poly-silicon by a thermal cycle step. Since the channel is located within the body region, a stable channel would mean a deeper body junction, such a deeper body junction has a characteristic semi-circular profile as shown in FIG. 1. However, it is appreciated that a deep body-junction will aggravate the JFET (Junction Field Effect Transistor) effect and will lead to early pinch-off in the area between adjacent body junctions as well as making the channel unnecessarily long. To alleviate adverse consequences of deeper body junctions, additional spacing between adjacent body junctions will be necessary and this will result in a larger device size.

Furthermore, the lateral diffusion rate of impurities inside the epitaxial layer is lower than the vertical diffusion rate by about 20%. At cell corners, the diffusing rate of impurities at the cell corners is even lower and is only about 50% of the vertical diffusion rate due to spreading effect at the cell corners. This diffusion rate differential is even more noticeable for P-type impurities. For a MOSFET with a closed cell structure, for example, with a square or hexagonal cell structure, the lower diffusion rate along the lateral devices will mean a shorter channel length at the cell corners and this will result in early punch-through breakdown of the channel at the cell corners.

Hence, it will be beneficial if there can be provided improved power MOSFETs and methods or processes for making same, which alleviate shortcomings of conventional MOSFETs or conventional methods of making same. In the description below and throughout the specification, the terms “poly-silicon”, “polysilicon” or “poly” mean polycrystalline silicon unless the context otherwise requires.

### OBJECT OF THE INVENTION

Accordingly, it is an object of the present invention to provide MOSFETs and means and methods of making same which alleviate shortcomings of conventional MOSFETs and methods of making same. At a minimum, it is an object of the present invention to provide the public with a useful alternative of power MOSFET devices and methods of making same.

### SUMMARY OF THE INVENTION

According to this invention, there is described a method of forming a MOSFET on an epitaxial layer of a semiconductor substrate of a first conductivity type, the MOSFET comprises a source region of the first conductivity type and a body region of a second conductivity type.

The method comprises the steps of:—
Forming a body region on the epitaxial layer of the substrate,
Forming a source region within the body region, the source region to be formed is defined by polysilicon gates which are formed after formation of the body region but before doping of the body region to form the source region, whereby a device channel is formed between edges of the source and body regions,
Forming a body contact intermediate the body region and the source region, the body contact is formed after the source region is masked leaving portions corresponding to the body contact exposed.

The polysilicon gates are re-shaped after the formation of the body region but before formation of the source region to serve as a self-aligning mask which defines the source region to facilitate implantation of source impurities with a high spatial precision.

The method requires only 4 masking steps and represents significant improvements over prior art which requires at least 5 masking steps. In addition, this method provides a processing method for forming a MOSFET with a self-aligned ultra-shallow body.

Preferably, body region is formed after a plurality of polysilicon gates have been formed, source regions of the MOSFET are defined between the polysilicon gates, each polysilicon gate comprises a layer of polysilicon etch stopper sandwiched between two layers of polysilicon.

Preferably, the sandwiched layer comprises a polysilicon etch stopping oxide.

Preferably, the sandwiched layer comprises LP-TEOS or oxide.

Preferably, a layer of LP-TEOS or oxide of a thickness of 100-1000 A is applied between the layers of polysilicon.

Preferably, two layers of polysilicon are formed on the substrate before formation of said polysilicon gates, the polysilicon layers comprise a thin polysilicon layer and a thick polysilicon layer, the thin polysilicon layer is intermediate the thick polysilicon layer and the substrate.

Preferably, a polysilicon layer of a thickness of between 200-2000 A is applied to form the thin polysilicon layer.

Preferably, a polysilicon layer of a thickness of between 3000-8000 A is applied to form the thick polysilicon layer.

Preferably, the body region is formed by ion implantation into the substrate when after the thick polysilicon and LP-TEO or oxide layers have been etched but before the thin polysilicon layer is etched.

Preferably, a mask for forming the source region comprises a spacer which is formed around a polysilicon gate after formation of the body region, the distance between an adjacent pair of spacers correspond to the source region.

Preferably, a mask for forming the source region comprises a spacer which is formed around a polysilicon gate after formation of the body region, the footprint of the spacer defines the device channel.

Preferably, wherein a mask for forming the body contact comprises a spacer which is formed around a polysilicon gate after formation of the source region, the distance between an adjacent pair of spacers correspond to the source region.

Preferably, a nitride spacer is applied to form the spacer for defining the body contact.

Preferably, the method comprises the additional steps of:13
Forming a body region implantation masking window on the epitaxial layer of the substrate before formation of the body region, the implantation masking window comprises a plurality of distributed polysilicon gates on a layer of polysilicon, each polysilicon gate comprises a layer of polysilicon on a polysilicon etch stop layer.

Preferably, the method comprises the additional steps of:—
Removing polysilicon above the source region after formation of the P-body region.

Preferably, the method comprises the additional steps of:—
Forming a body region implantation masking window on the epitaxial layer of the substrate before formation of the body region, the implantation masking window comprises a plurality of distributed polysilicon gates on a layer of polysilicon, each polysilicon gate comprises a layer of polysilicon on a polysilicon etch stop layer.
Predefined pass-through regions and blocking regions wherein doping impurities of a second conductivity type and at a prescribed energy level can pass through the pass-through regions of the implantation masking window and penetrate into the epitaxial layer for forming an initial body region while the same doping impurities are blocked by the blocking regions.
Implanting doping impurities of the second conductivity type at said prescribed energy level into the epitaxial layer through the implantation masking window, whereby an initial body region of the second conductivity type is formed.
Expanding the initial body region along a lateral direction to form a body region by a thermal step,
Forming a plurality of gate elements on the substrate, each said gate element having a cross-sectional profile comprising a head portion and a shoulder portion, said head portion being adapted to block doping impurities into the underlying substrate during an impurities implantation step, said shoulder portion being thinner than said head portion and being adapted to allow partial passage of doping impurities into the underlying substrate during said impurities implantation step,
Implanting impurities into the substrate from the gate side of the substrate to form a body region of the second conductivity type, said body region extends from underneath the shoulder portion of a gate element to underneath the shoulder portion of an adjacent gate element, said body region comprises a head portion and a shoulder portion, the head portion of said body region extends deeper into the substrate than the shoulder portion of said body region and extends between the shoulder portions of the pair of gate elements, and
Implanting impurities into the substrate from the gate side of the substrate to form a source region of the first conductivity type.

Preferably, the formation process of the gate elements comprises the following steps:—
forming an active region defined by a boundary of field oxide,
growing a layer of gate oxide,
depositing a first polysilicon layer on the gate oxide,
depositing a layer of polysilicon etching resistant substances on the first polysilicon layer,
depositing a second polysilicon layer on the layer of polysilicon etching resistant substances,
masking to define and etching to form a plurality of polysilicon protrusions, the polysilicon protrusions protrude from the layer of polysilicon etching resistant substances,
removing exposed polysilicon etching resistant substances so that the polysilicon protrusions change to a protrusion with a top layer of polysilicon and an underneath layer of polysilicon etching resistant substances,
depositing a further layer of polysilicon to interconnect the first and second polysilicon layers, whereby a plurality of polysilicon islands are formed,
forming a spacer around each said polysilicon islands,
Removing the remaining exposed first polysilicon layer.

Preferably, the gate element being formed by embedding an intermediate layer of substances which are resistant to polysilicon etching between two polysilicon layers.

Preferably, the implanting of impurities into the substrate to form the source region takes place when the shoulder portion of the gate elements is covered by a spacer.

Preferably, impurities of the body region are driven deeper into the substrate before the spacers are formed around the polysilicon islands.

Preferably, a source region is formed by implanting impurities of the first conductivity type after the spacers have been formed.

Preferably, a deep body region is formed by implanting impurities of the second conductivity type after the spacers have been formed.

According to the invention, there is provided a MOSFET comprising an epitaxial layer of a semiconductor substrate of a first conductivity type, the MOSFET comprises a polysilicon gate, a source region of the first conductivity type and a body region of a second conductivity type, the polysilicon gate comprises a first layer of polysilicon and a second layer of polysilicon sandwiching a layer of polysilicon etch stop substances.

Preferably, the polysilicon layers comprises a thin polysilicon layer and a thick polysilicon layer, the thin polysilicon layer is intermediate the substrate and the thick polysilicon

Preferably, the thin polysilicon layer has a thickness of between 200-2000 A.

Preferably, the thick polysilicon layer has a thickness of between 3000-8000 A.

Preferably, the sandwiched layer comprises LP-TEOS.

Preferably, the layer of LP-TEOS has a thickness of 100-1000 A.

Preferably, the first and second polysilicon layers are joined by a polysilicon connector which surrounds the polysilicon gate.

Preferably, the polysilicon connector has a thickness of between 2000 A to 7000 A.

### BRIEF DESCRIPTION OF THE DRAWINGS

Preferred embodiments of the invention will be explained in further detail below by way of example and with reference to the accompanying drawings, in which:—

FIG. 1 shows a cross-sectional view of a conventional VDMOS showing the shape and configuration of the body region in particular,

FIG. 2 is a cross-sectional view showing a semiconductor substrate coated with a layer of a field oxide and applied with a photo-resist mask,

FIG. 3 shows a cross-sectional view of the substrate of FIG. 2 after the active region has been formed and the residual photo-resist has been removed,

FIG. 4 shows the substrate of FIG. 3 coated with a layer of gate oxide,

FIG. 5 shows the substrate of FIG. 4 applied with a first layer of polysilicon,

FIG. 6 shows the substrate of FIG. 5 applied with a layer of LP-TEOS,

FIG. 7 shows the substrate of FIG. 6 applied with a second layer of polysilicon and a layer of nitride as a polysilicon etch stopper,

FIG. 8 shows the substrate of FIG. 7 applied with a polysilicon etch mask,

FIG. 9 is a top plan view of a substrate carrying a plurality of VDMOS transistor cells,

FIG. 10 is a perspective view of the substrate across the Section A′-A after the substrate of FIG. 8 has been etched and the residual polysilicon masking removed,

FIG. 11 is a perspective view of the substrate across the Section B′-B after the substrate of FIG. 8 has been etched and the residual polysilicon masking removed,

FIG. 12 schematically illustrates an ion implantation process to form the body region,

FIG. 13 shows an in-situ polysilicon deposition process after the ion implantation process of FIG. 12,

FIG. 14 illustrates a process of body region drive-in after the step of FIG. 13,

FIG. 15 illustrates a process of blanket polysilicon etch of the substrate of FIG. 14,

FIG. 16 illustrates a process of P body-contact and source implantation of the substrate of FIG. 15,

FIG. 17 illustrates a process of inter-dielectric deposition to the substrate of FIG. 16,

FIG. 18 illustrates the step of contact masking and etching to the substrate of FIG. 17,

FIG. 19 illustrates a process of PECVD nitride deposition to the substrate of FIG. 18,

FIG. 20 illustrates a process of blanket nitride etch to the substrate of FIG. 19.

FIG. 21 illustrates a step of P+ body implantation to the substrate of FIG. 20,

FIG. 22 illustrates a process of nitride removal from the substrate of FIG. 21,

FIG. 23 illustrates a process of barrier metal and metal deposition to the substrate of FIG. 22,

FIG. 24 illustrates a process of metal masking and etching of FIG. 23, and

FIG. 25 illustrates a process of backside polishing and backside metal sputtering to the substrate of FIG. 24.

### DETAILED DESCRIPTION OF THE PREFERRED EMBODIMENTS

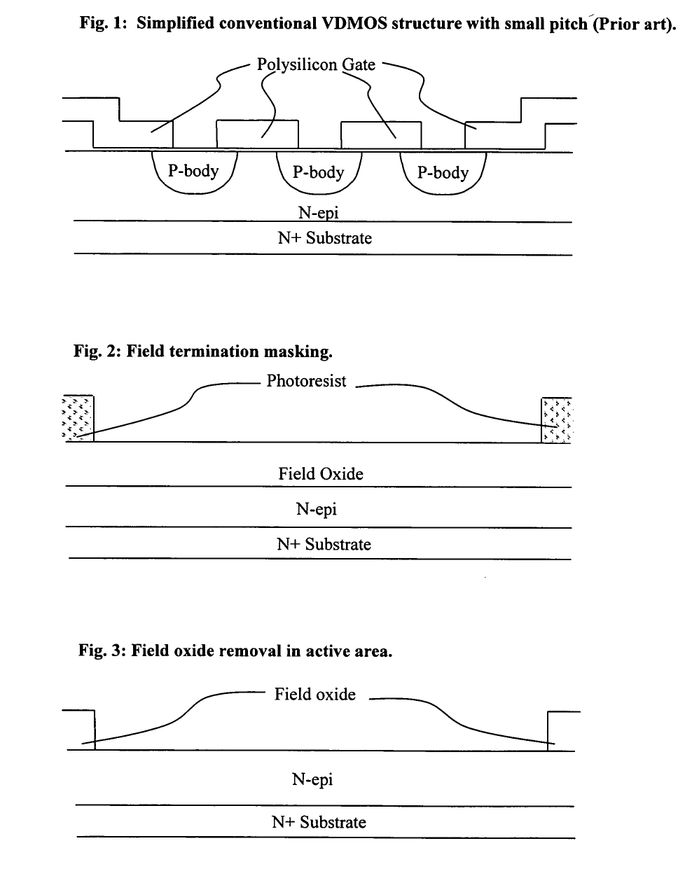

A MOSFET device is characterised by its gate, drain and source terminals. A typical MOSFET is formed on a silicon substrate on which there is an epitaxial layer of an appropriate and predetermined thickness and doping concentration. The silicon substrate and the epitaxial layer are doped with impurities of the first conductivity type, although the substrate is usually more heavily doped than the epitaxial layer. A body region which is doped with impurities of a second conductivity type is formed in the epitaxial layer and extends laterally between a pair of adjacent gate terminals, as shown in FIG. 1. A source region of the first conductivity type is embedded within the body region and is separated from the underlying silicon substrate and epitaxial layer by the body region. The gate region comprises a conductive layer, or, as an example, a doped polycrystalline silicon conductive layer. The drain electrode is usually formed on the backside surface of the substrate, i.e., underneath the substrate of FIG. 1.

Throughout this specification, it will be appreciated that if the P-type conductivity is referred to as the first conductivity type, the second conductivity type will be the N-type conductivity and vice versa. This is because the P-type and the N-type conductivity are the known alternative conductivity types that are relevant to commercial semiconductor technology. Although a MOSFET with a substrate which is doped with the N-type impurities is used as an example in this specification and hence the first conductivity type is the N-type conductivity, it would be understood by persons skilled in the art that the description below will apply mutatis mutandis to a power MOSFET with a substrate doped with P-type impurities in which case the first conductivity type will be the P-type. Boron and arsenic are examples of impurities suitable for doping the silicon substrate respectively into the P— and the N-type conductivity.

In order to reduce the on-resistance and to provide an adequate current or power handling capacity, a MOSFET device, especially a power MOSFET, typically comprises a plurality of power MOSFET cells, which are fabricated on a common substrate, connected in parallel. Hence, it will be appreciated, for example, that the gate region of a power MOSFET device actually comprises a plurality of gate elements each of which is the gate of an individual power MOSFET cell.

In the examples below, a power MOSFET device with the N conductivity type as the first conductivity type having an N-channel is illustrated as a convenient example. Of course, this invention also applies to devices with either P— or N-channel without loss of generality.

As an example, a process flow for fabricating a high density N-channel planar power MOSFET transistor with an ultra-shallow body-junction, a short channel length and a deep body-contact-junction is described in the present invention.

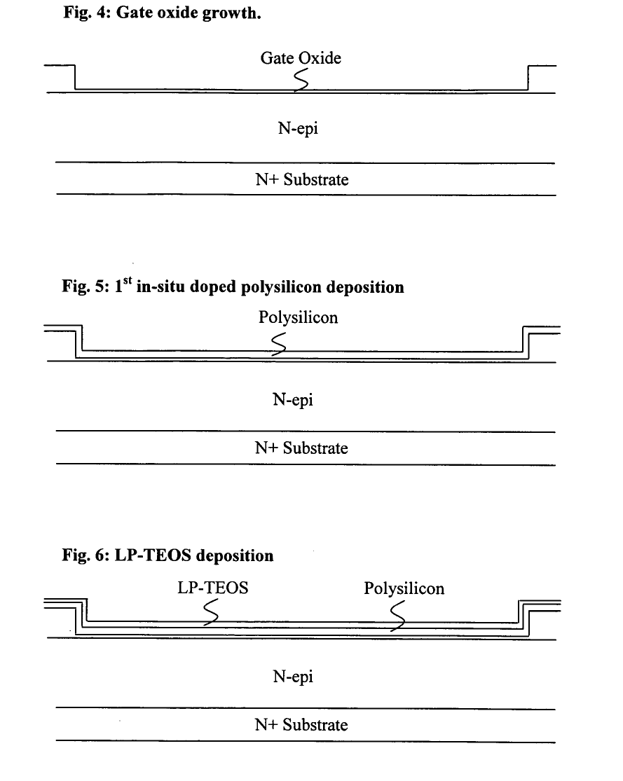

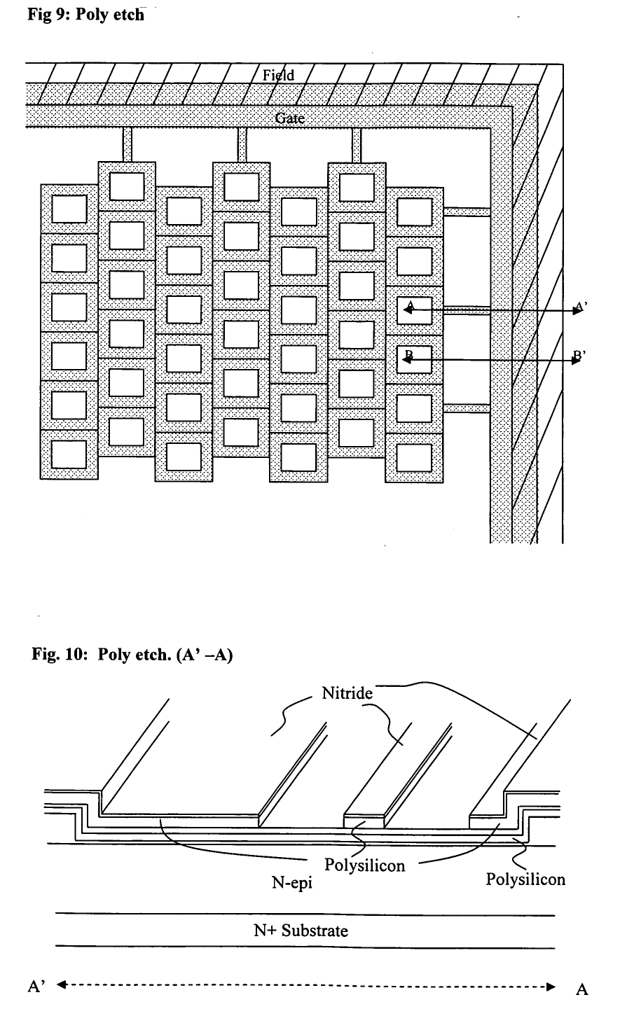

Referring to FIGS. 2 to 25, an N-channel power MOSFET is formed on an N-type epitaxial (“epi”) layer, which is grown on an N+ substrate. A layer of thermal oxide 1000 to 6000 A is grown on the epi as field oxide. A first masking layer (field termination mask) is used to define the active area as shown in FIG. 2. Wet or dry etching process is used to remove the field oxide in the defined active area as shown in FIG. 3. After removing the field oxide in the active area, a layer of gate oxide (60 A to 1000 A) is grown as shown in FIG. 4.

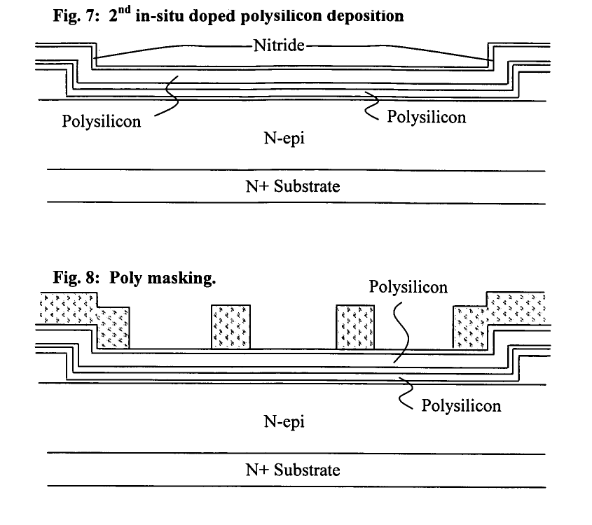

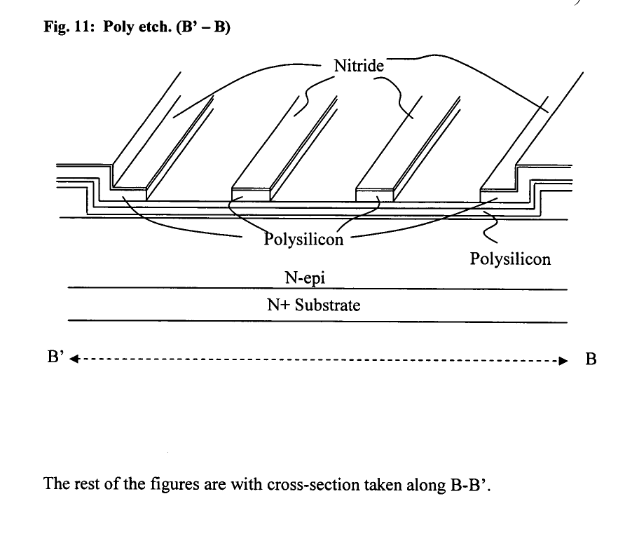

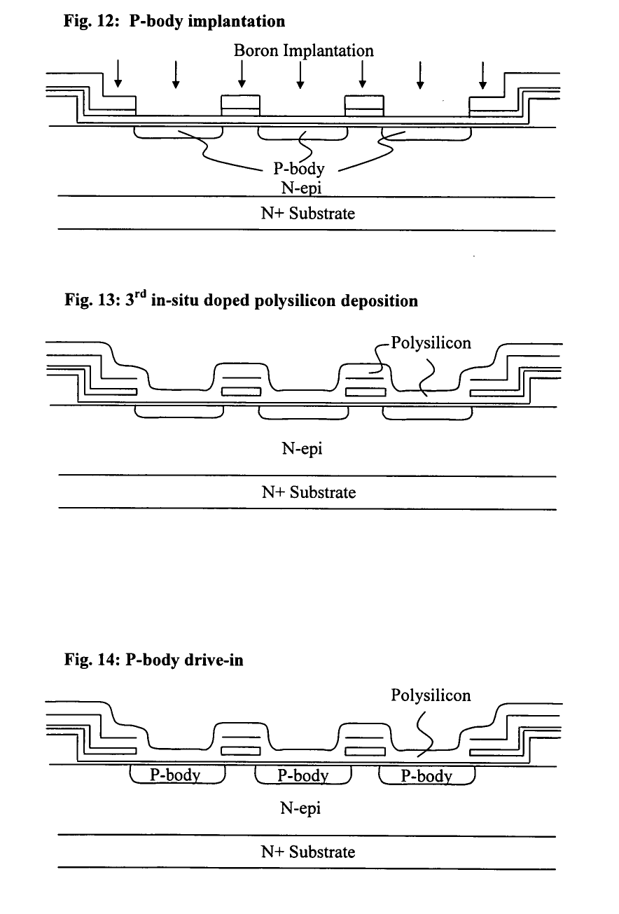

A distinct multi-layer of film stack is deposited on top of the gate oxide. This distinct multi-layer of film stack consists of a thin layer of polysilicon (200 A to 2000 A) as shown in FIG. 5, a thin layer of LP-TEOS (100 A to 1000 A) or oxide as shown in FIG. 6., and a thick layer of polysilicon (3000 A to 8000 A) as shown in FIG. 7. These two layers of polysilicon are insitu-doped polysilicon and they can be doped by implantation or other methods. An optional thin layer of nitride around 300 A to 700 A deposited on top of the thick layer of polysilicon to serve as poly etch stopper can be used to prevent polysilicon loss on top of the “stacked poly gate”. A second mask (poly-gate mask) is used to define the poly-gate in the active area as well as the gate pad in the field area as shown in FIG. 8. The exposed nitride and polysilicon are then etched away and the underneath thin layer of oxide is acted as an etch stop layer to prevent any further etching into the thin layer of firstly deposited polysilicon (FIG. 11). Oxide etch is used to remove the layer of oxide stop as shown in FIG. 12.

A blanket P-type implantation (Boron dose of 1E13 to 1E14 with 80 keV to 200 keV) is performed to form a P-body as shown in FIG. 12. The impurities implanted through the thin layer of polysilicon to form an ultra-shallow body-junction, but the thick poly region blocks the impurities to reach the silicon surface where the drift region is formed. This P-body formation is self-aligned to the gate-poly. A third layer of polysilicon (2000 A to 7000 A) is deposited and is used to connect the first and second polysilicon together as shown in FIG. 13. A short thermal cycle is then performed to activate and drive-in the P-type impurities to form an ultra-shallow P-body junction as shown in FIG. 14. Blanket poly etch is employed to create poly spacers along the sidewalls of the poly stack as shown in FIG. 15. With the poly spacer and the corresponding ultra-shallow P-body junction, the channel length is defined underneath the gate poly.

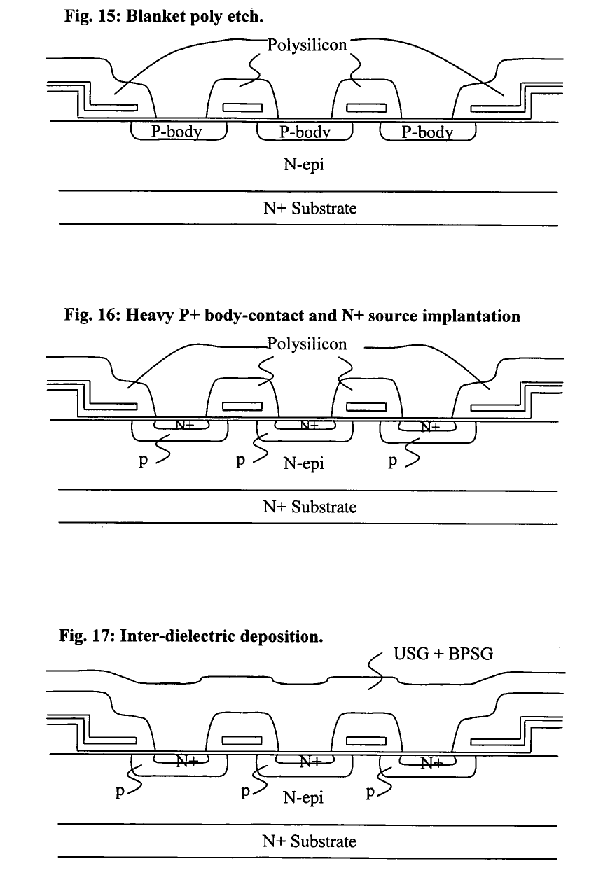

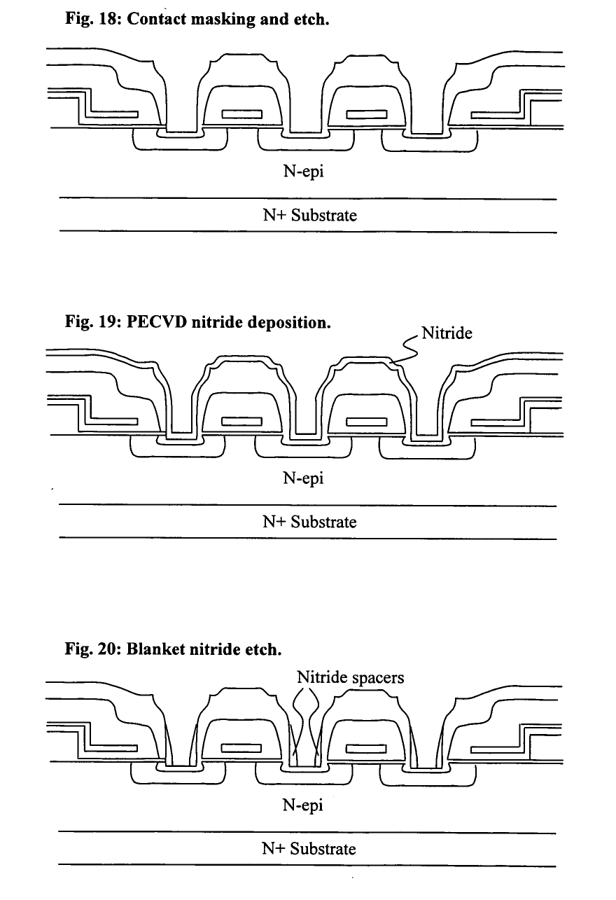

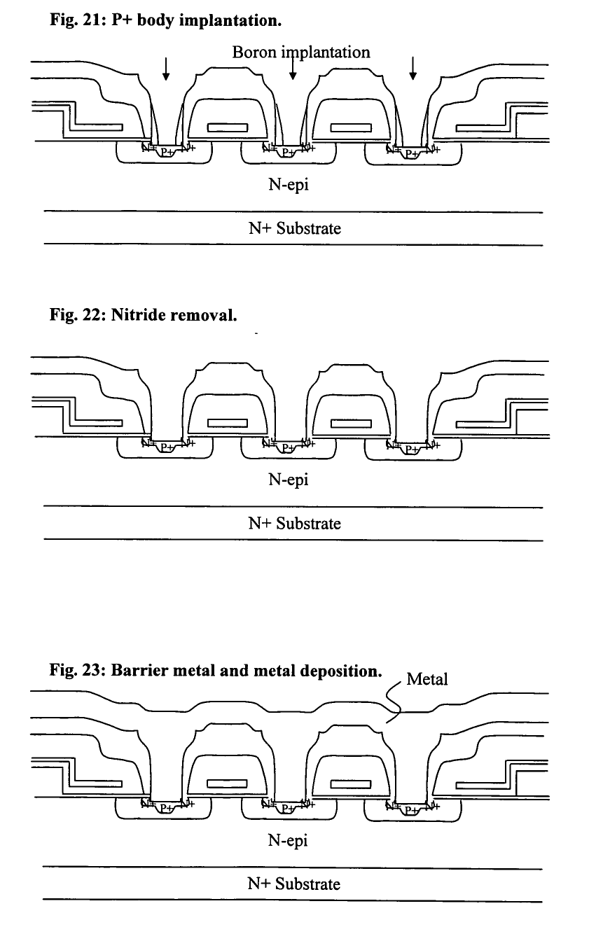

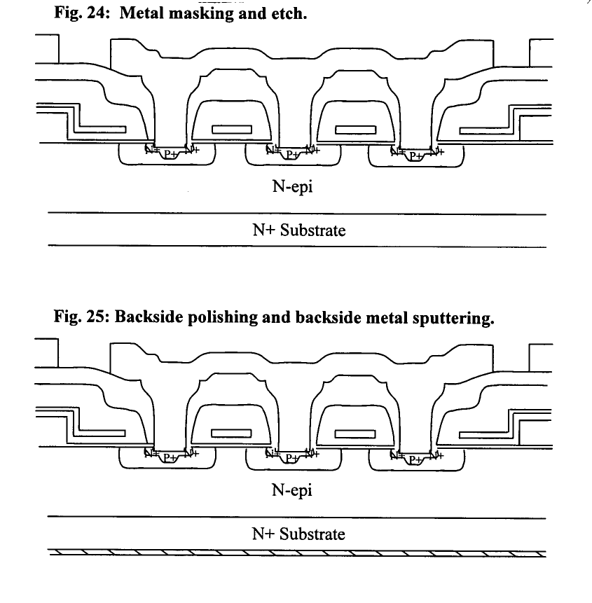

A blanket high energy P-type implant (boron, 80˜120 kev, 1E13˜1E14) and a blanket N-type implant (arsenic, 40˜120 eV, 1E15˜1E16) is used to form the deep P body-contact and N+source region, respectively, as shown in FIG. 16. USG (Undoped Silicate Glass) and BPSG (Borophosphosilicate Glass) are deposited as the ILD (Inter-Layer Dielectric). A thermal cycle is used to flow the BPSG to achieve better planarization and anneal the source impurities as shown in FIG. 17. A third mask (contact mask) is employed to define the contact region as shown in FIG. 18. A layer of nitride (500 A-1000 A) is deposited as shown in FIG. 19 and is then etched back by anisotropic etching to create nitride spacers in the contact holes as shown in FIG. 20. 1000 A to 2000 A of silicon at the surface is removed in the nitride etch-back. A blanket P+ implant (boron, 1E15 to 5E15) is performed to form the P+ body contacts as shown in FIG. 21. Hot H3PO4 (Phosphoric acid) is used to remove the nitride spacers in the contact holes as shown in FIG. 22. A layer of barrier metal and aluminium are then deposited to fill the contact holes as shown in FIG. 23. A fourth mask (metal mask) is used to define the source and gate pads as shown in FIG. 24. Then the wafers are sent for sintering. Finally, the wafers will receive back-grinding to reduce the substrate resistance, and backside metal deposition as shown in FIG. 25.

While the present invention has been explained by reference to the preferred embodiments of power MOSFETs described above, it will be appreciated that the embodiments are illustrated as examples to assist understanding of the present invention and are not meant to be restrictive on the scope and spirit of the present invention. The scope of this invention should be determined from the general principles and spirit of the invention as described above. In particular, variations or modifications which are obvious or trivial to persons skilled in the art, as well as improvements made on the basis of the present invention, should be considered as falling within the scope and boundary of the present invention.

Furthermore, while the present invention has been explained by reference to power MOSFETs, it should be appreciated that the invention can apply, whether with or without modification, to other power MOSFETs and other similar semiconductor devices without loss of generality.

1. A method of forming a MOSFET on an epitaxial layer of a semiconductor substrate of a first conductivity type, the MOSFET comprises a source region of the first conductivity type and a body region of a second conductivity type, the method comprises the steps of:—
Forming a body region on the epitaxial layer of the substrate,
Forming a source region within the body region, the source region to be formed is defined by polysilicon gates which are formed after formation of the body region but before doping of the body region to form the source region, whereby a device channel is formed between edges of the source and body regions,
Forming a body contact intermediate the body region and the source region, the body contact is formed after the source region is masked leaving portions corresponding to the body contact exposed.

2. A method of forming a MOSFET according to claim 1, wherein the body region is formed after a plurality of polysilicon gates have been formed, source regions of the MOSFET are defined between the polysilicon gates, each polysilicon gate comprises a layer of polysilicon etch stopper sandwiched between two layers of polysilicon.

3. A method of forming a MOSFET according to claim 2, wherein the sandwiched layer comprises a polysilicon etch stopping oxide.

4. A method of forming a MOSFET according to claim 2, wherein the sandwiched layer comprises LP-TEOS or oxide.

5. A method of forming a MOSFET according to claim 4, wherein a layer of LP-TEOS or oxide of a thickness of 100-1000 A is applied between the layers of polysilicon.

6. A method of forming a MOSFET according to claim 1, wherein two layers of polysilicon are formed on the substrate before formation of said polysilicon gates, the polysilicon layers comprise a thin polysilicon layer and a thick polysilicon layer, the thin polysilicon layer is intermediate the thick polysilicon layer and the substrate.

7. A method of forming a MOSFET according to claim 6, wherein a polysilicon layer of a thickness of between 200-2000 A is applied to form the thin polysilicon layer.

8. A method of forming a MOSFET according to claim 7, wherein a polysilicon layer of a thickness of between 3000-8000 A is applied to form the thick polysilicon layer.

9. A method of forming a MOSFET according to claim 7, wherein the body region is formed by ion implantation into the substrate when after the thick polysilicon and LP-TEO or oxide layers have been etched but before the thin polysilicon layer is etched.

10. A method of forming a MOSFET according to claim 7, wherein a mask for forming the source region comprises a spacer which is formed around a polysilicon gate after formation of the body region, the distance between an adjacent pair of spacers correspond to the source region.

11. A method of forming a MOSFET according to claim 7, wherein a mask for forming the source region comprises a spacer which is formed around a polysilicon gate after formation of the body region, the footprint of the spacer defines the device channel.

12. A method of forming a MOSFET according to claim 7, wherein a mask for forming the body contact comprises a spacer which is formed around a polysilicon gate after formation of the source region, the distance between an adjacent pair of spacers correspond to the source region.

13. A method of forming a MOSFET according to claim 12, wherein a nitride spacer is applied to form the spacer for defining the body contact.

14. A method of forming a MOSFET according to claim 1, the method comprises the additional steps of:—
Forming a body region implantation masking window on the epitaxial layer of the substrate before formation of the body region, the implantation masking window comprises a plurality of distributed polysilicon gates on a layer of polysilicon, each polysilicon gate comprises a layer of polysilicon on a polysilicon etch stop layer.

15. A method of forming a MOSFET according to claim 14, the method comprises the additional steps of:—
Removing polysilicon above the source region after formation of the P-body region.

16. A method of forming a MOSFET according to claim 1, the method comprises the additional steps of:—
Forming a body region implantation masking window on the epitaxial layer of the substrate before formation of the body region, the implantation masking window comprises a plurality of distributed polysilicon gates on a layer of polysilicon, each polysilicon gate comprises a layer of polysilicon on a polysilicon etch stop layer.
Predefined pass-through regions and blocking regions wherein doping impurities of a second conductivity type and at a prescribed energy level can pass through the pass-through regions of the implantation masking window and penetrate into the epitaxial layer for forming an initial body region while the same doping impurities are blocked by the blocking regions.
Implanting doping impurities of the second conductivity type at said prescribed energy level into the epitaxial layer through the implantation masking window, whereby an initial body region of the second conductivity type is formed.
Expanding the initial body region along a lateral direction to form a body region by a thermal step,
Forming a plurality of gate elements on the substrate, each said gate element having a cross-sectional profile comprising a head portion and a shoulder portion, said head portion being adapted to block doping impurities into the underlying substrate during an impurities implantation step, said shoulder portion being thinner than said head portion and being adapted to allow partial passage of doping impurities into the underlying substrate during said impurities implantation step,
Implanting impurities into the substrate from the gate side of the substrate to form a body region of the second conductivity type, said body region extends from underneath the shoulder portion of a gate element to underneath the shoulder portion of an adjacent gate element, said body region comprises a head portion and a shoulder portion, the head portion of said body region extends deeper into the substrate than the shoulder portion of said body region and extends between the shoulder portions of the pair of gate elements, and
Implanting impurities into the substrate from the gate side of the substrate to form a source region of the first conductivity type.

17. A method according to claim 1, wherein the formation process of the gate elements comprises the following steps:—
forming an active region defined by a boundary of field oxide,
growing a layer of gate oxide,
depositing a first polysilicon layer on the gate oxide,
depositing a layer of polysilicon etching resistant substances on the first polysilicon layer,
depositing a second polysilicon layer on the layer of polysilicon etching resistant substances,
masking to define and etching to form a plurality of polysilicon protrusions, the polysilicon protrusions protrude from the layer of polysilicon etching resistant substances,
removing exposed polysilicon etching resistant substances so that the polysilicon protrusions change to a protrusion with a top layer of polysilicon and an underneath layer of polysilicon etching resistant substances,
depositing a further layer of polysilicon to interconnect the first and second polysilicon layers, whereby a plurality of polysilicon islands are formed,
forming a spacer around each said polysilicon islands,
Removing the remaining exposed first polysilicon layer.

18. A method according to claim 17, wherein the gate element being formed by embedding an intermediate layer of substances which are resistant to polysilicon etching between two polysilicon layers.

19. A method according to claim 18, wherein the implanting of impurities into the substrate to form the source region takes place when the shoulder portion of the gate elements is covered by a spacer.

20. A method according to claim 19, wherein impurities of the body region are driven deeper into the substrate before the spacers are formed around the polysilicon islands.

21. A method according to claim 20, wherein a source region is formed by implanting impurities of the first conductivity type after the spacers have been formed.

22. A method according to claim 21, wherein a deep body region is formed by implanting impurities of the second conductivity type after the spacers have been formed.

23. A MOSFET comprising an epitaxial layer of a semiconductor substrate of a first conductivity type, the MOSFET comprises a polysilicon gate, a source region of the first conductivity type and a body region of a second conductivity type, the polysilicon gate comprises a first layer of polysilicon and a second layer of polysilicon sandwiching a layer of polysilicon etch stop substances.

24. A MOSFET according to claim 23, wherein the polysilicon layers comprises a thin polysilicon layer and a thick polysilicon layer, the thin polysilicon layer is intermediate the substrate and the thick polysilicon.

25. A MOSFET according to claim 24, wherein the thin polysilicon layer has a thickness of between 200-2000 A.

26. A MOSFET according to claim 24, wherein the thick polysilicon layer has a thickness of between 3000-8000 A.

27. A MOSFET according to claim 23, wherein the sandwiched layer comprises LP-TEOS.

28. A MOSFET according to claim 27, wherein the layer of LP-TEOS has a thickness of 100-1000 A.

29. A MOSFET according to claim 23, wherein the first and second polysilicon layers are joined by a polysilicon connector which surrounds the polysilicon gate.

30. A MOSFET according to claim 23, wherein the polysilicon connector has a thickness of between 2000 A to 7000 A.
